(19) United States
(12) Patent Application Publication
(10) Pub. No.: US 2026/0168078 A1
(43) Pub. Date: Jun. 18, 2026

(54) DEPOSITION MASK, METHOD FOR MANUFACTURING DEPOSITION MASK, AND ELECTRONIC DEVICE

(71) Applicant: Samsung Display Co., Ltd., Yongin-si (KR)

(72) Inventor: Sung Woon KIM, Yongin-si (KR)

(21) Appl. No.: 19/373,469

(22) Filed: Oct. 29, 2025

(30) Foreign Application Priority Data
Dec. 12, 2024 (KR) 10-2024-0184843

(51) Int. Cl. C23C 14/04; H10H 29/01

(52) U.S. Cl. CPC C23C 14/042; H10H 29/012

(57) ABSTRACT

A deposition mask includes a mask frame including a nickel-iron alloy, a first inorganic layer above the mask frame, the mask frame and the first inorganic layer defining opening patterns, and a second inorganic layer above the first inorganic layer, and defining cell openings at cell opening regions.

### CROSS-REFERENCE TO RELATED APPLICATION

The present application claims priority to, and the benefit of, Korean Patent Application No. 10-2024-0184843, filed on December 12, 2024, in the Korean Intellectual Property Office, the entire disclosure of which is incorporated herein by reference.

### BACKGROUND

### 1. Field

The present disclosure relates to a deposition mask, a method for manufacturing the deposition mask, and an electronic device.

### 2. Description of the Related Art

With increasing interest in information display in recent years, research and development of display devices have been continuously conducted.

### SUMMARY

The present disclosure improves reliability of a continuous deposition process.

The present disclosure is not limited to the above-mentioned aspects, and other aspects that are not mentioned will be clearly understood by those skilled in the art from the following description.

A deposition mask according to one or more embodiments includes a mask frame including a nickel-iron alloy, a first inorganic layer above the mask frame, the mask frame and the first inorganic layer defining opening patterns, and a second inorganic layer above the first inorganic layer, and defining cell openings at cell opening regions.

The opening patterns may overlap the cell opening regions.

The first inorganic layer may include silicon oxide, wherein the second inorganic layer includes silicon nitride.

The second inorganic layer may further define an opening hole between the cell opening regions.

The opening hole may be between adjacent ones of the cell opening regions.

The opening hole may overlap the mask frame.

The opening hole may overlap the first inorganic layer.

The opening hole may expose the first inorganic layer.

A display device may include a first electrode, a second electrode above the first electrode, and a light-emitting layer between the first electrode and the second electrode, the light-emitting layer being manufactured using the deposition mask.

An electronic device may include a processor, and a display device including pixels, and may be configured to display an image under control of the processor, the display device being manufactured using the deposition mask.

A method for manufacturing a deposition mask according to one or more embodiments includes forming a first inorganic layer above a base substrate, forming a second inorganic layer above the first inorganic layer, forming cell opening regions in the second inorganic layer, bonding a template onto the second inorganic layer, removing the base substrate from the first inorganic layer, bonding a mask frame to a surface of the first inorganic layer, and removing the template from the second inorganic layer.

A coefficient of thermal expansion of the mask frame may be less than a coefficient of thermal expansion of the base substrate.

The mask frame may include a nickel-iron alloy.

The method may further include etching the first inorganic layer to form opening patterns.

The opening patterns may overlap the cell opening regions.

The cell opening regions may correspond to cell openings defined by the second inorganic layer.

The first inorganic layer may include silicon oxide, wherein the second inorganic layer includes silicon nitride.

The method may further include forming an opening hole between adjacent ones of the cell opening regions.

The adjacent ones of the cell opening regions may be separated from each other by the opening hole.

The opening hole may expose the first inorganic layer.

Details of other embodiments are included in the description and the drawings.

According to the above, it is possible to improve the reliability of the deposition process by reducing or minimizing the deformation of the deposition mask due to the temperature rise during the continuous deposition using the mask frame including a nickel-iron alloy (e.g., INVAR^{TM} (INVAR^{TM} being a registered trademark of APERAM ALLOYS IMPHY, JOINT STOCK COMPANY, FRANCE)).

Aspects according to the embodiments are not limited by the content illustrated above, and more various aspects are included in the present specification.

### BRIEF DESCRIPTION OF THE DRAWINGS

FIG. 1 is a side view showing one or more embodiments of a deposition apparatus.

FIGS. 2 to 4 are side views showing one or more embodiments of a deposition mask.

FIG. 5 is a block diagram showing one or more embodiments of a display device.

FIG. 6 is a block diagram showing one or more embodiments of any one of the sub-pixels of FIG. 5.

FIG. 7 is a plan view showing one or more embodiments of the display panel of FIG. 5.

FIG. 8 is an exploded perspective view showing a part of the display panel of FIG. 7.

FIG. 9 is a block diagram of an electronic device according to one or more embodiments.

FIG. 10 is schematic diagrams of an electronic device in accordance with various embodiments.

FIGS. 11 to 16 are process operation cross-sectional views of a method of manufacturing a deposition mask according to one or more embodiments.

FIGS. 17 to 22 are process operation cross-sectional views of a method of manufacturing a deposition mask according to one or more embodiments.

FIGS. 23 to 28 are process operation cross-sectional views of a method of manufacturing a deposition mask according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

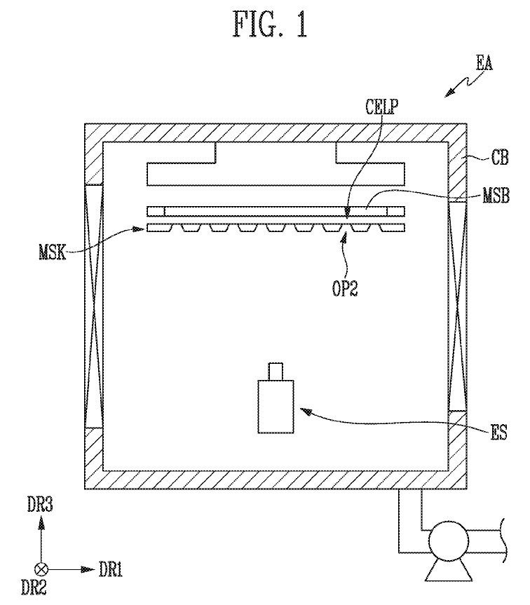

FIG. 1 is a side view showing one or more embodiments of a deposition apparatus.

Referring to FIG. 1, a deposition apparatus EA according to one or more embodiments may include a chamber CB, a deposition source ES, and a deposition mask MSK.

The chamber CB may have a space therein. The internal space of the chamber CB may be a working space provided for a deposition process. An object to be deposited, or to receive a deposition material, may be accommodated (or located) inside the chamber CB. For example, a mother substrate MSB to receive a deposition material may be located inside the chamber CB.

The deposition source ES may be located inside the chamber CB. The deposition source ES may contain the deposition material, and may supply the deposition material to the internal space of the chamber CB. The deposition material may include a material that forms a pattern layer (e.g., a predetermined pattern layer, such as a light-emitting layer) on a mother substrate (MSB). The deposition source ES may apply energy (e.g., thermal energy, light energy, vibrational energy, or the like) to the deposition material to vaporize or sublimate the deposition material. As an example, the deposition source ES may include a heater therein, and the operation of the heater may heat the deposition material inside the deposition source ES to melt or sublimate the deposition material. The deposition source ES may be replaceable. The deposition source ES can be replaced by a new deposition source when the contained deposition material is exhausted.

The deposition mask MSK may be located between the mother substrate MSB and the deposition source ES. The deposition mask MSK may be aligned to face the deposition object. The deposition mask MSK may block deposition material in some areas, and might not block the deposition material in other areas. Accordingly, the deposition material may be selectively deposited only on a corresponding region of the deposition target. The cell opening region CELP may be a region in which the other partial region where the deposition material is not blocked is provided. The deposition mask MSK may include opening patterns OP2 that respectively overlap the cell opening regions CELP. The cell opening region CELP and the opening pattern OP2 may overlap in the third direction DR3. The deposition material may be provided to the deposition object (or mother substrate MSB) through the cell opening regions CELP and the opening patterns OP2.

In one or more embodiments, one deposition mask MSK may be used to perform deposition on the deposition targets concurrently, or at the same time. In this case, a plurality of cell opening regions CELP may be provided. For example, the cell opening regions CELP may be arranged along a first direction DR1 and a second direction DR2 crossing the first direction DR1. The cell opening regions CELP may be spaced apart from one another.

Deformation of the deposition mask MSK may occur due to a temperature rise in the process of continuous deposition using the deposition mask MSK, and the position(s) of the cell opening regions CELP may be changed due to the deformation of the deposition mask MSK. Thus, the deposition mask MSK may use a mask frame including a nickel-iron alloy (e.g., INVAR^{TM} (INVAR^{TM} being a registered trademark of APERAM ALLOYS IMPHY, JOINT STOCK COMPANY, FRANCE)) to reduce or minimize thermal expansion of the mask frame to keep the spacing of the cell opening regions CELP constant. Therefore, the reliability of the continuous deposition process can be improved.

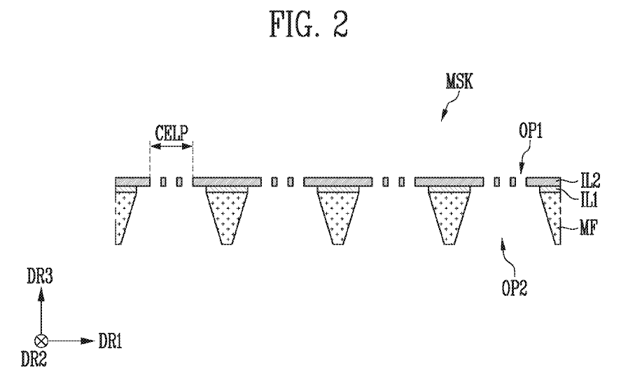

FIGS. 2 to 4 are side views showing one or more embodiments of a deposition mask.

Referring to FIG. 2, the deposition mask MSK may include a mask frame MF, a first inorganic layer IL1, and/or a second inorganic layer IL2.

In one or more embodiments, the mask frame MF may be composed of (e.g., may include), a material with a low coefficient of thermal expansion to reduce or minimize deformation due to temperature rise during continuous deposition. As an example, the mask frame MF may be composed of a material having a coefficient of thermal expansion that is less than or lower than the coefficient of thermal expansion of the silicon wafer. The mask frame MF may include INVAR^{TM} (INVAR^{TM} being a registered trademark of APERAM ALLOYS IMPHY, JOINT STOCK COMPANY, FRANCE). For example, the mask frame MF may include a nickel-iron alloy of which 36% consists of nickel and 64% consists of iron. As described above, in the case where the mask frame MF of the deposition mask MSK includes INVAR^{TM} (INVAR^{TM} being a registered trademark of APERAM ALLOYS IMPHY, JOINT STOCK COMPANY, FRANCE), even if the temperature rises during continuous deposition, it is possible to reduce or minimize thermal expansion of the mask frame MF, and thus it is possible to improve the reliability of the deposition process.

A first inorganic layer IL1 may be located on the mask frame MF (as used herein, “located on” may mean “above”). The first inorganic layer IL1 may include, but is not necessarily limited to, silicon oxide (SiOx). The first inorganic layer IL1 may be bonded on the mask frame MF. In one or more embodiments, an adhesive layer may be further located between the first inorganic layer IL1 and the mask frame MF, but is not necessarily limited thereto. According to one or more embodiments, the first inorganic layer IL1 and the mask frame MF may be coupled in various manners, such as brazing, soldering, anodic bonding, or silicon fusion bonding.

A second inorganic layer IL2 may be located on the first inorganic layer IL1. The second inorganic layer IL2 may be located directly on the first inorganic layer IL1. The second inorganic layer IL2 may include, but is not necessarily limited to, silicon nitride (SiNx).

The cell opening regions CELP may be defined in the second inorganic layer IL2. The cell opening regions CELP may be provided with cell openings OP1. The cell openings OP1 of the cell opening region CELP may penetrate the second inorganic layer IL2.

In one or more embodiments, the opening patterns OP2 may each overlap the cell opening regions CELP (e.g., the opening patterns OP2 may respectively overlap the cell opening regions CELP). The opening pattern OP2 may overlap the cell openings OP1 (e.g., one opening pattern OP2 may overlap two or more cell openings OP1). The opening pattern OP2 may be formed in, or defined by, the first inorganic layer IL1 and the mask frame MF. The opening pattern OP2 can penetrate through the first inorganic layer IL1 and the mask frame MF. Accordingly, deposition material may be provided to the mother substrate MSB through the cell openings OP1 and the opening patterns OP2.

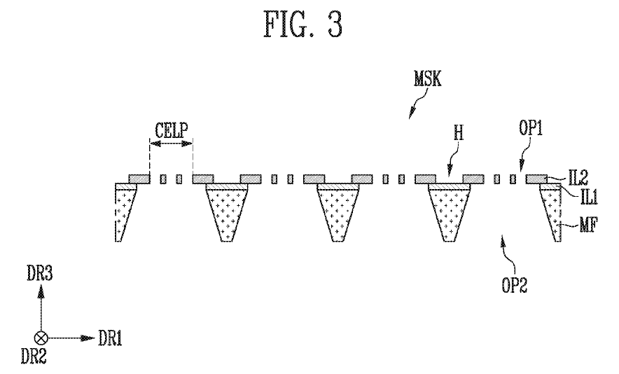

Referring to FIG. 3, the deposition mask MSK may further include opening holes H. The opening holes H may overlap the first inorganic layer IL1 in the third direction DR3. The opening holes H may overlap the mask frame MF in the third direction DR3. The opening holes H may penetrate the second inorganic layer IL2. The opening holes H may penetrate the second inorganic layer IL2 to at least partially expose the first inorganic layer IL1.

The opening holes H may be located between respective ones of the cell opening regions CELP. For example, the opening hole H may be located between adjacent ones of the cell opening regions CELP spaced apart from each other. The opening holes H may serve to separate adjacent cell opening regions CELP from one another. Even if the position of at least one of the cell opening regions CELP is changed due to a temperature rise in the process of continuous deposition, it is possible to reduce or prevent the likelihood of the cell opening regions CELP being separated from each other to affect the position of the adjacent cell opening regions CELP.

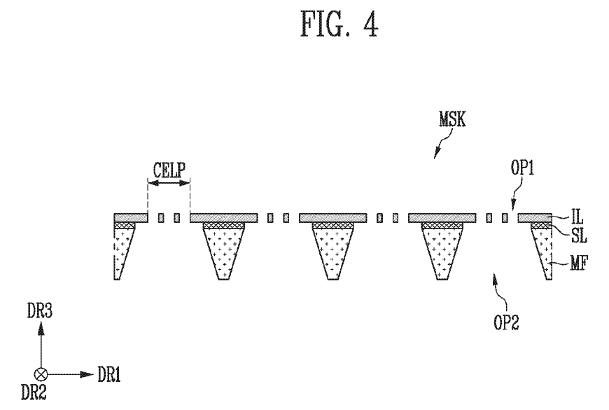

Referring to FIG. 4, a silicon layer SL may be located on the mask frame MF. The coefficient of thermal expansion of the mask frame MF may be less than or lower than the coefficient of thermal expansion of the silicon layer SL. This makes it possible to reduce or minimize the thermal expansion of the mask frame MF even if the temperature rises during the continuous deposition, thereby improving the reliability of the deposition process. In one or more embodiments, the silicon layer SL may be bonded on the mask frame MF. In one or more embodiments, an adhesive layer may be further located between the silicon layer SL and the mask frame MF, but the present disclosure is not limited thereto. According to one or more embodiments, the silicon layer SL and the mask frame MF may be coupled in various manners, such as brazing, soldering, anodic bonding, or silicon fusion bonding.

An inorganic layer IL may be located on the silicon layer SL. The inorganic layer IL may be located directly on the silicon layer SL. The inorganic layer IL may include, but is not limited to, silicon nitride (SiNx).

The cell opening regions CELP may be defined in the inorganic layer IL. The cell opening regions CELP may be provided with cell openings OP1. The cell openings OP1 of the cell opening region CELP may penetrate the inorganic layer IL.

In one or more embodiments, the opening patterns OP2 may respectively overlap the cell opening regions CELP. The opening pattern OP2 may respectively overlap one or more of the cell openings OP1. The opening pattern OP2 may be formed in, or defined by, the silicon layer SL and the mask frame MF. The opening pattern OP2 can penetrate through the silicon layer SL and the mask frame MF. Accordingly, deposition material may be provided to the mother substrate MSB through the cell openings OP1 and the opening patterns OP2.

According to the above, it is possible to reduce or minimize the thermal expansion of the mask frame MF by using the mask frames MF including INVAR^{TM} (INVAR^{TM} being a registered trademark of APERAM ALLOYS IMPHY, JOINT STOCK COMPANY, FRANCE). Therefore, even if the temperature rises during the continuous deposition, the interval between the cell opening regions CELP can be kept constant, so that the reliability of the continuous deposition process can be improved.

Hereinafter, a display device manufactured using the deposition mask MSK described with reference to FIGS. 2 to 4 and an electronic device including the same will be described.

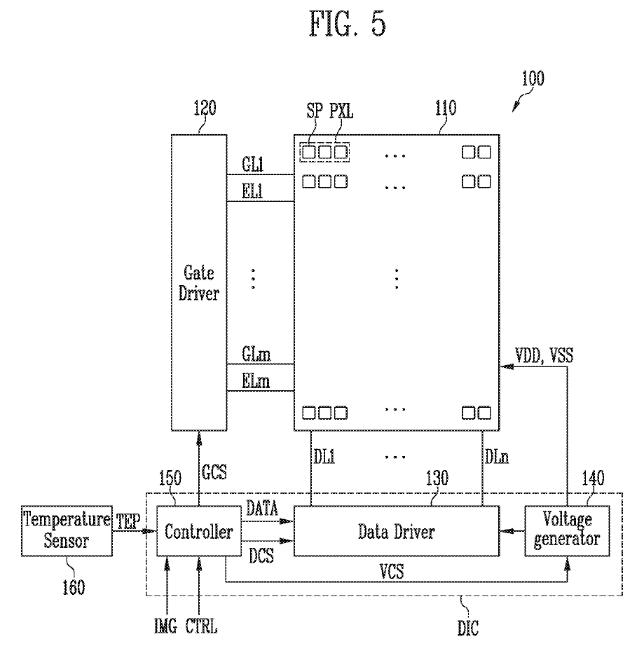

FIG. 5 is a block diagram showing one or more embodiments of a display device.

The display device 100 in FIG. 5 can be manufactured using the above-described deposition mask MSK.

Referring to FIG. 5, the display device 100 may include a display panel 110, a gate driver 120, a data driver 130, a voltage generator 140, and a controller 150.

The display panel 110 may include sub-pixels SP. The sub-pixels SP may be connected to the gate driver 120 through the first to m-th gate lines GL1 to GLm. The sub-pixels SP may be connected to the data driver 130 through the first to n-th data lines DL1 to DLn.

Each of the sub-pixels SP may include at least one light-emitting element configured to generate light. Accordingly, each of the sub-pixels SP may generate light of a corresponding color, such as red, green, blue, cyan, magenta, yellow, or the like. Two or more sub-pixels of the sub-pixels SP may constitute one pixel PXL. For example, as illustrated in FIG. 5, three sub-pixels SP may constitute one pixel PXL.

The gate driver 120 may be connected to the sub-pixels SP arranged in the row direction through the first to m-th gate lines GL1 to GLm. The gate driver 120 may output gate signals to the first to m-th gate lines GL1 to GLm in response to the gate control signal GCS. In one or more embodiments, the gate control signal GCS may include a start signal indicating the start of each frame, a horizontal synchronization signal for outputting gate signals in synchronization with the timing at which the data signals are applied, or the like.

In one or more embodiments, first to m-th light-emitting control lines EL1 to ELm connected to the sub-pixels SP in the row direction may be further provided. In this case, the gate driver 120 may include a light-emitting control driver configured to control the first to m-th light-emitting control lines EL1 to ELm, and the light-emitting control driver may operate according to the control of the controller 150.

The gate driver 120 may be located on one side of the display panel 110. However, embodiments are not so limited. For example, the gate driver 120 may be divided into two or more drivers that are physically and/or logically separated, and such drivers may be located on one side of the display panel 110 and the other side of the display panel 110 opposite to the one side. As such, the gate driver 120 may be located at the periphery of the display panel 110 in various forms according to embodiments.

The data driver 130 may be connected to the sub-pixels SP arranged in the column direction through the first to n-th data lines DL1 to DLn. The data driver 130 may receive the image data DATA and the data control signal DCS from the controller 150. Data driver 130 may operate in response to a data control signal DCS. In one or more embodiments, the data control signal DCS may include a source start pulse, a source shift clock, a source output enable signal, or the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Corresponding sub-pixels SP can thus generate light corresponding to the data signals. Thus, an image can be displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. For example, the voltage generator 140 may be configured to generate voltages by receiving an input voltage from outside the display device 100, adjusting the received voltage, and regulating the adjusted voltage.

The voltage generator 140 may generate a first power supply voltage VDD and a second power supply voltage VSS. The generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In one or more other embodiments, the first power supply voltage VDD or the second power supply voltage VSS may be provided by an external device of the display device 100.

In addition, the voltage generator 140 may generate various voltages. For example, the voltage generator 140 may generate an initialization voltage that is applied to the sub-pixels SP. For example, in a sensing operation for sensing electrical characteristics of transistors and/or light-emitting elements of the sub-pixels SP, a reference voltage (e.g., a predetermined reference voltage) may be applied to the first to n-th data lines DL1 to DLn, and the voltage generator 140 may generate such a reference voltage.

The controller 150 can control various operations of the display device 100. The controller 150 may receive the input image data IMG and the control signal CTRL for controlling display thereof from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 and output the image data DATA. In one or more embodiments, the controller 150 may output the image data DATA by aligning the input image data IMG to fit the sub-pixels SP in units of rows.

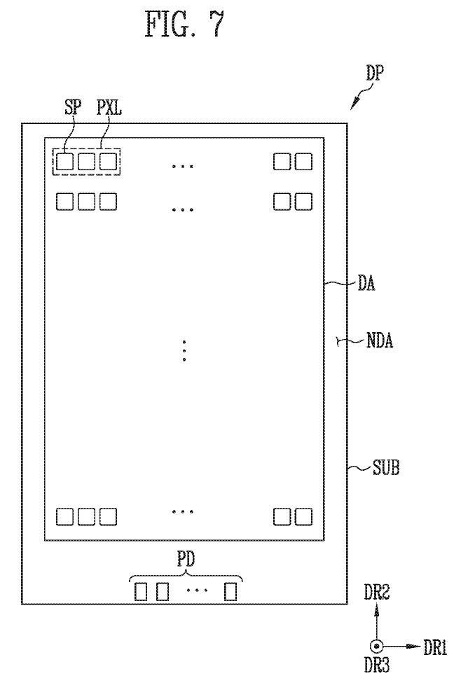

Two or more components of the data driver 130, the voltage generator 140, and the controller 150 may be mounted in one integrated circuit. As shown in FIG. 7, data driver 130, voltage generator 140, and controller 150 may be included in a driver integrated circuit DIC. In this case, data driver 130, voltage generator 140, and controller 150 may be functionally distinct components within one driver integrated circuit DIC. In other embodiments, at least one of the data driver 130, the voltage generator 140, and the controller 150 may be provided as a component separate from a driver integrated circuit DIC.

The display device 100 may include at least one temperature sensor 160. Temperature sensor 160 may be configured to sense a temperature in its surroundings and generate temperature data TEP indicative of the sensed temperature. In one or more embodiments, the temperature sensor 160 may be located adjacent to the display panel 110 and/or a driver integrated circuit DIC.

The controller 150 may control various operations of the display device 100 in response to the temperature data TEP. In one or more embodiments, the controller 150 may adjust luminance of an image output from the display panel 110 in response to the temperature data TEP. For example, the controller 150 may adjust the data signals and the first and second power supply voltages VDD and VSS by controlling components, such as the data driver 130 and/or the voltage generator 140.

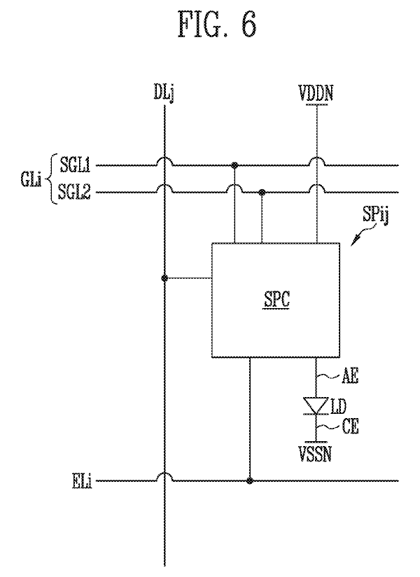

FIG. 6 is a block diagram showing one or more embodiments of any one of the sub-pixels of FIG. 5. In FIG. 6, a sub-pixel SPij arranged in an i-th row (i is an integer greater than or equal to 1 and less than or equal to m) and a j-th column (j is an integer greater than 1 and less than n) among the sub-pixels SP in FIG. 5 is shown.

Referring to FIG. 6, the sub-pixel SPij may include a sub-pixel circuit SPC and a light-emitting element LD.

The light-emitting element LD may be connected between the first power supply voltage node VDDN and the second power supply voltage node VSSN. The first power supply voltage node VDDN may be a node that delivers the first power supply voltage VDD of FIG. 5, and the second power supply voltage node VSSN may be a node that delivers the second power supply potential VSS of FIG. 5.

The anode electrode AE of the light-emitting element LD may be connected to the first power supply voltage node VDDN through the sub-pixel circuit SPC, and the cathode electrode CE of the light-emitting element LD may be coupled to the second power supply voltage node VSSN. For example, the anode electrode AE of the light-emitting element LD may be connected to the first power supply voltage node VDDN through one or more transistors included in the sub-pixel circuit SPC.

The sub-pixel circuit SPC may be connected to an i-th gate line GLi among the first to m-th gate lines GL1 to GLm in FIG. 5, an i-th light-emitting control line ELi among the first to M-th light-emitting control lines EL1 to ELm in FIG. 4, and a j-th data line DLj among the first to n-th data lines DL1 to DLn in FIG. 5. The sub-pixel circuit SPC may be configured to control the light-emitting element LD in accordance with signals received through these signal lines.

The sub-pixel circuit SPC may operate in response to a gate signal received through the i-th gate line GLi. The i-th gate line GLi may include one or more sub-gate lines. In one or more embodiments, the i-th gate line GLi may include first and second sub-gate lines SGL1, SGL2. The sub-pixel circuit SPC may operate in response to gate signals received through the first and second sub-gate lines SGL1, SGL2. Thus, in the case where the i-th gate line GLi includes two or more sub-gate lines, the sub-pixel circuit SPC can operate in response to gate signals received through the sub-gate lines.

The sub-pixel circuit SPC may operate in response to a light-emitting control signal received via the i-th light-emitting control line ELi. In one or more embodiments, the i-th light-emitting control line ELi may include one or more sub-light-emitting control lines. When the i-th light-emitting control line ELi includes two or more sub-light-emitting control lines, the sub-pixel circuit SPC may operate in response to light-emitting control signals received through the sub-light-emitting control lines.

The sub-pixel circuit SPC can receive a data signal through the j-th data line DLj. The sub-pixel circuit SPC may store a voltage corresponding to the data signal in response to at least one of the gate signals received via the first and second sub-gate lines SGL1 and SGL2. The sub-pixel circuit SPC may adjust the current flowing from the first power supply voltage node VDDN to the second power supply voltage node VSSN through the light-emitting element LD according to the stored voltage, in response to the light-emitting control signal received through the i-th light-emitting control line ELi. Thus, the light-emitting element LD can generate light with a luminance corresponding to the data signal.

FIG. 7 is a plan view showing one or more embodiments of the display panel of FIG. 5.

Referring to FIG. 7, one or more embodiments of the display panel DP (e.g., the display panel 110 of FIG. 5) may include a display area DA and a non-display area NDA. The display panel DP can display an image through the display region DA. The non-display area NDA may be located in the periphery of the display area DA. The display panel DP may include a substrate SUB, sub-pixels SP, and pads PD.

When the display panel DP is used as a display screen of a head-mounted display device (HMD), a virtual reality (VR) device, a mixed reality (MR) device, an augmented reality (AR) device, or the like, the display panel DP may be positioned very close to an eye of a user. In this case, a relatively high degree of integration of the sub-pixels SP may be required. To increase the degree of integration of the sub-pixels SP, the substrate SUB may be provided as a silicon substrate. On the substrate SUB that is a silicon substrate, the sub-pixels SP and/or the display panel DP can be formed. The substrate SUB may correspond to the mother substrate MSB of FIG. 1. The display device 100 including the display panel DP on the substrate SUB that is a silicon substrate can be referred to as an OLED on Silicon (OLEDoS) display device.

The sub-pixels SP may be located in the display region DA on the substrate SUB. The sub-pixels SP may be arranged in a matrix form along a first direction DR1, and along a second direction DR2 crossing the first direction DR1. However, embodiments are not so limited. For example, the sub-pixels SP may be arranged in a zigzag pattern along the first direction DR1 and the second direction DR2. For example, the sub-pixels SP may be arranged in a PENTILE^{TM} form (PENTILE^{TM} being a registered trademark of Samsung Display Co., Ltd., Republic of Korea). The first direction DR1 may be a row direction, and the second direction DR2 may be a column direction. Two or more sub-pixels of the sub-pixels SP may constitute one pixel PXL.

In the non-display region NDA on the substrate SUB, a component for controlling the sub-pixels SP can be placed. For example, wirings connected to the sub-pixels SP, such as the first to m-th gate lines GL1 to GLm and the first to n-th data lines DL1 to DLn in FIG. 5, can be located in the non-display region NDA.

At least one of the gate driver 120, the data driver 130, the voltage generator 140, the controller 150, and the temperature sensor 160 in FIG. 5 can be integrated into the non-display region NDA of the display panel DP. In one or more embodiments, the gate driver 120 in FIG. 5 may be mounted on the display panel DP and located in the non-display area NDA. In one or more other embodiments, the gate driver 120 may be implemented as an integrated circuit separate from the display panel DP. In one or more embodiments, the temperature sensor 160 may be located in the non-display area NDA to sense the temperature of the display panel DP.

Pads PD may be located in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD can interface the display panel DP to other components of the display device 100. In one or more embodiments, voltages and signals suitable for operation of components included in the display panel DP can be provided from the driver integrated circuit DIC in FIG. 5 through the pads PD. For example, the first to n-th data lines DL1-DLn may be connected to the driver integrated circuit DIC via pads PD. For example, the first and second power supply voltages VDD and VSS may be received from the driver integrated circuit DIC via the pads PD. For example, in the case where the gate driver 120 is mounted on the display panel DP, the gate control signal GCS can be transmitted from the driver integrated circuit DIC to the gate driver 120 through the pads PD.

In one or more embodiments, a circuit board may be electrically connected to the pads PD by using a conductive adhesive member, such as an anisotropic conductive film. At this time, the circuit board may be a flexible circuit board (FPCB) or a flexible film having a flexible material. The driver integrated circuit DIC may be mounted to a circuit board and electrically connected to pads PD.

In one or more embodiments, the display region DA may have various shapes. The display region DA may have a shape of a closed loop including straight and/or curved sides. For example, the display region DA can have shapes of a polygon, a circle, a semicircle, an ellipse, and the like.

The display panel DP may have a flat display surface. In one or more other embodiments, the display panel DP may have an at least partially round display surface. In one or more embodiments, the display panel DP may be bendable, foldable, or rollable. In such cases, the display panel DP and/or the substrate SUB may include materials having a flexible property.

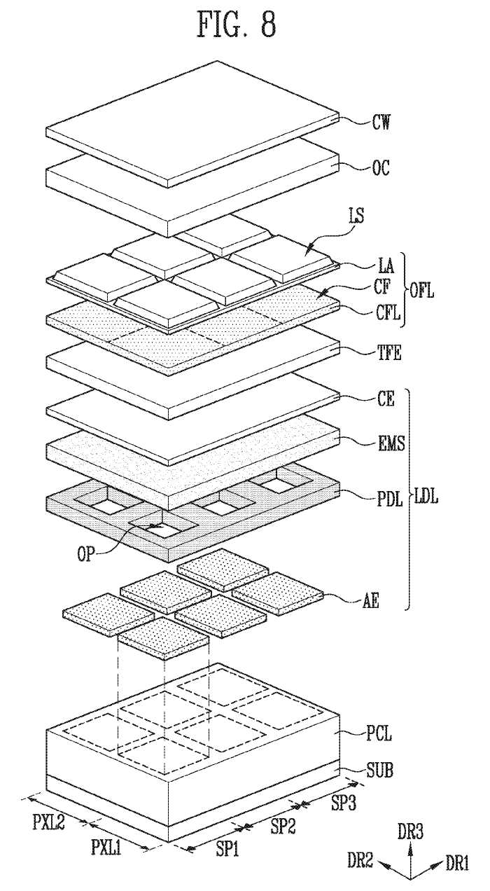

FIG. 8 is an exploded perspective view showing a part of the display panel of FIG. 7.

Referring to FIGS. 7 and 8, each of the first and second pixels PXL1 and PXL2 may include first to third sub-pixels SP1 to SP3. However, embodiments are not so limited. For example, each of the first and second pixels PXL1 and PXL2 may include four sub-pixels, or may include two sub-pixels.

In FIG. 8, the first to third sub-pixels SP1 to SP3 have square shapes when viewed in the third direction DR3 crossing the first and second directions DR1 and DR2, and may have the same sizes as each other. However, embodiments are not so limited. The first to third sub-pixels SP1 to SP3 can be deformed to have various shapes.

The display panel DP can include a substrate SUB, a pixel circuit layer PCL, a light-emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator layer (SeOI), or the like. In one or more other embodiments, the substrate SUB may include a glass substrate. In one or more other embodiments, the substrate SUB may include a polyimide (PI) substrate.

The pixel circuit layer PCL can be located on the substrate SUB. The substrate SUB and/or the pixel circuit layer PCL may include insulating layers and conductive patterns located between the insulating layers. The conductive patterns of the pixel circuit layer PCL can function as at least part of circuit elements, wirings, or the like. The conductive patterns may include copper, although embodiments are not so limited.

The circuit elements may include a sub-pixel circuit SPC (see FIG. 6) of each of the first to third sub-pixels SP1 to SP3. A sub-pixel circuit SPC may include transistors and one or more capacitors. Each transistor may include a semiconductor portion including a source region, a drain region, and a channel region, and also may include a gate electrode overlapped with the semiconductor portion. In the case where the substrate SUB is provided as a silicon substrate, a semiconductor portion is included in the substrate SUB, and a gate electrode may be included in the pixel circuit layer PCL as a conductive pattern of the pixel circuit layer PCB. In one or more embodiments, in the case where the substrate SUB is provided as a glass substrate or a PI substrate, the semiconductor portion and the gate electrode may be included in the pixel circuit layer PCL. Each capacitor may include electrodes spaced apart from one another. For example, each capacitor may include electrodes spaced apart from one another on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the first to third sub-pixels SP1 to SP3, for example, a gate line, a light-emitting control line, a data line, and the like. The wires may further include a wire connected to the first power supply voltage node VDDN of FIG. 6. The wires may further include a wire connected to the second power supply voltage node VSSN of FIG. 6.

The light-emitting element layer LDL may include anode electrodes AE, a pixel-defining layer PDL, a light-emitting structure EMS, and a cathode electrode CE.

The anode electrodes AE may be located on the pixel circuit layer PCL. The anode electrodes AE may be electrically connected to circuit elements of the pixel circuit layer PCL. The anode electrodes AE may include an opaque conductive material capable of reflecting light, but embodiments are not limited thereto.

A pixel-defining layer PDL may be located on the anode electrodes AE. The pixel-defining layer PDL may include (e.g., may define) an opening OP exposing a part of each of the anode electrodes AE. The opening OP of the pixel-defining layer PDL may be understood as light-emitting regions corresponding to the first to third sub-pixels SP1 to SP3, respectively.

In one or more embodiments, the pixel-defining layer PDL may include an inorganic material. In this case, the pixel-defining layer PDL may include multiple stacked inorganic layers. For example, the pixel-defining layer PDL may include silicon oxide (SiOx) and/or silicon nitride (SiNx). In one or more other embodiments, the pixel-defining layer PDL may include an organic material. However, the material of the pixel-defining layer PDL is not limited thereto.

The light-emitting structure EMS may be located on the anode electrodes AE exposed by the opening OP of the pixel-defining layer PDL. In one or more embodiments, the cell openings OP1 of the deposition mask MSK may expose the opening OP of the pixel-defining layer PDL, and the light-emitting structure EMS may be deposited on the opening OP in the pixel-defining layer PDL by using the deposition mask MSK. The light-emitting structure EMS may include a light-emitting layer configured to generate light, an electron transport layer configured to transport electrons, a hole transport layer configured to transmit holes, and the like. In one or more embodiments, portions of the light-emitting structure EMS corresponding to the first to third sub-pixels SP1 to SP3 are separated from each other, and each of the separated light-emitting structures EMS may be located in the opening OP of the pixel-defining layer PDL.

The cathode electrode CE may be located on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may include a metal material, or may include a transparent conductive material, so as to be relatively thin. In one or more embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In one or more other embodiments, the cathode electrode CE may include at least one of silver (Ag), magnesium (Mg), and mixtures thereof. However, the material of the cathode electrode CE is not limited thereto.

Any one of the anode electrodes AE, a portion of the light-emitting structure EMS overlapping therewith, and a portion of the cathode electrode CE overlapping therewith may be understood to constitute one light-emitting element LD (see FIG. 6). Each of the light-emitting elements of the first to third sub-pixels SP1 to SP3 may include one anode electrode AE, a portion of a light-emitting structure EMS overlapping therewith, and a portion of a cathode electrode CE overlapping therewith. In each of the first to third sub-pixels SP1 to SP3, holes injected from the anode electrode AE (e.g., a first electrode) and electrons injected from the cathode electrode CE (e.g., a second electrode) are transported into the light-emitting layer of the light-emitting structure EMS to form excitons, and when the excitons transition from the excited state to the ground state, light can be generated. The luminance of light may be determined according to the amount of current flowing through the light-emitting layer. Depending on the configuration of the light-emitting layer, the wavelength range of the generated light may be determined.

An encapsulation layer TFE may be located on the cathode electrode CE. The encapsulation layer TFE can cover the light-emitting element layer LDL and/or the pixel circuit layer PCL. The encapsulation layer TFE may be configured to reduce or prevent oxygen and/or moisture or the like penetrating into the light-emitting element layer LDL. In one or more embodiments, the encapsulation layer TFE may include a structure in which one or more inorganic films and one or more organic films are alternately laminated. For example, the inorganic film may include silicon nitride (SiNx), silicon oxide (SiOx), silicon oxynitride (SiOxNy), or the like. For example, the organic film may include an organic insulating material, such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic film and the inorganic film of the encapsulation layer TFE are not limited thereto.

The optical functional layer OFL can be arranged on the encapsulation layer TFE. The optical functional layer OFL may include a color filter layer CFL and a lens array LA.

The color filter layer CFL may be located between the encapsulation layer TFE and the lens array LA. The color filter layer CFL may be configured to filter light emitted from the light-emitting structure EMS to selectively output light of a wavelength range or color corresponding to each sub-pixel. The color filter layer CFL includes color filters CF respectively corresponding to the first to third sub-pixels SP1 to SP3, and each of the color filters CF is capable of passing light in a wavelength range corresponding to the corresponding sub-pixel. For example, the color filter corresponding to the first sub-pixel SP1 may pass light of red color, the color filter corresponds to the second sub-pixel SP2 may pass light of green color, and the color filter correspond to the third sub-pixel SP3 may pass light of blue color. Depending on the light emitted from the light-emitting structure EMS of each sub-pixel, at least part of the color filters CF may be omitted.

The lens array LA may be located on the color filter layer CFL. The lens array LA may include lenses LS respectively corresponding to the first to third sub-pixels SP1 to SP3. Each of the lenses LS may output light emitted from the light-emitting structure EMS to an intended path, thereby improving light exit efficiency. The lens array LA may have a relatively high refractive index. For example, the lens array LA may have a higher refractive index than the overcoat layer OC. In one or more embodiments, the lenses LS may include an organic material. In one or more embodiments, the lenses LS may include an acrylic material. However, the material of the lenses LS is not limited thereto.

In one or more embodiments, at least some of the color filters CF of the color filter layer CFL and at least some of lenses LS of the lens array LA may be shifted in a direction parallel to the plane defined by the first and second directions DR1 and DR2 relative to the opening OP of the pixel-defining layer PDL. As an example, in the central region of the display area DA, the center of the color filter and the center of the lens may be aligned with, or may overlap, the center of the opening OP of the corresponding pixel-defining layer PDL when viewed in the third direction DR3. For example, in a central region of the display area DA, the opening OP of the pixel-defining layer PDL may completely overlap the corresponding color filter of the color filter layer CFL and the corresponding lens of the lens array LA. In a region of the display region DA adjacent to the non-display region NDA, the center of the color filter and the center of the lens may be shifted in a planar direction from the center of the opening OP of the pixel-defining layer PDL when viewed in the third direction DR3.

For example, in a region adjacent to the non-display region NDA in the display region DA, the opening OP of the pixel-defining layer PDL may partially overlap the corresponding color filter of the color filter layer CFL and the corresponding lens of the lens array LA. Thus, in the center of the display region DA, light emitted from the light-emitting structure EMS can be efficiently output in the normal direction of the display surface. In the outer periphery of the display region DA, light emitted from the light-emitting structure EMS can be efficiently output in a direction inclined by an angle (e.g., a predetermined angle) with respect to the normal direction of the display surface.

The overcoat layer OC may be located on the lens array LA. The overcoat layer OC can cover the optical functional layer OFL, the encapsulation layer TFE, the light-emitting structure EMS, and/or the pixel circuit layer PCL. The overcoat layer OC may include various materials suitable for protecting the lower layers thereof from foreign matters, such as dust, moisture, and the like. For example, the overcoat layer OC may include at least one of an inorganic insulating film and an organic insulating film. For example, the overcoat layer OC may include epoxy, although embodiments are not so limited. The overcoat layer OC may have a lower refractive index than the lens array LA.

The cover window CW may be located on the over coat layer OC. The cover window CW may be configured to protect its lower layers. The cover window CW may have a higher refractive index than the over coat layer OC. The cover window CW may include glass, but embodiments are not limited thereto. For example, the cover window CW may be an encapsulation glass configured to protect components located at the bottom thereof. In other embodiments, the cover window CW may be omitted.

The display device 100 according to one or more embodiments can be applied to a variety of electronic devices. The electronic device according to one or more embodiments includes the display device 100 described above, and may further include a module or a device having another additional function in addition to the display device 100.

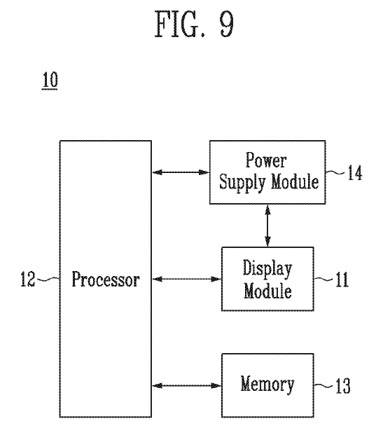

FIG. 9 is a block diagram of an electronic device according to one or more embodiments. Referring to FIG. 9, an electronic device 10 according to one or more embodiments may include a display module 11, a processor 12, a memory 13, and a power supply module 14.

The processor 12 may include at least one of a central processing unit (CPU), an application processor (AP), a graphics processing unit (GPU), a communication processor (CP), an image signal processor (ISP), or a controller.

Data information suitable for operation of the processor 12 or the display module 11 may be stored in the memory 13. When the processor 12 executes the application stored in the memory 13, the image data signal and/or the input control signal are transmitted to the display module 11, and the display module 11 may process the received signal and output the image information through the display screen.

The power supply module 14 may include a power supply module, such as a power adapter or a battery device, and a power conversion module that converts power supplied by the power supply module to generate power required for operation of the electronic device 10.

At least one of the above-described components of the electronic device 10 may be included in the display device 100 according to the above-described embodiments. In addition, some of the individual modules functionally included in one module may be included in the display device 100 and the other may be provided separately from the display device 100. For example, the display device 100 includes the display module 11, and the processor 12, the memory 13, and the power supply module 14 may be provided in a form of another device in the electronic device 10 other than the display device 100.

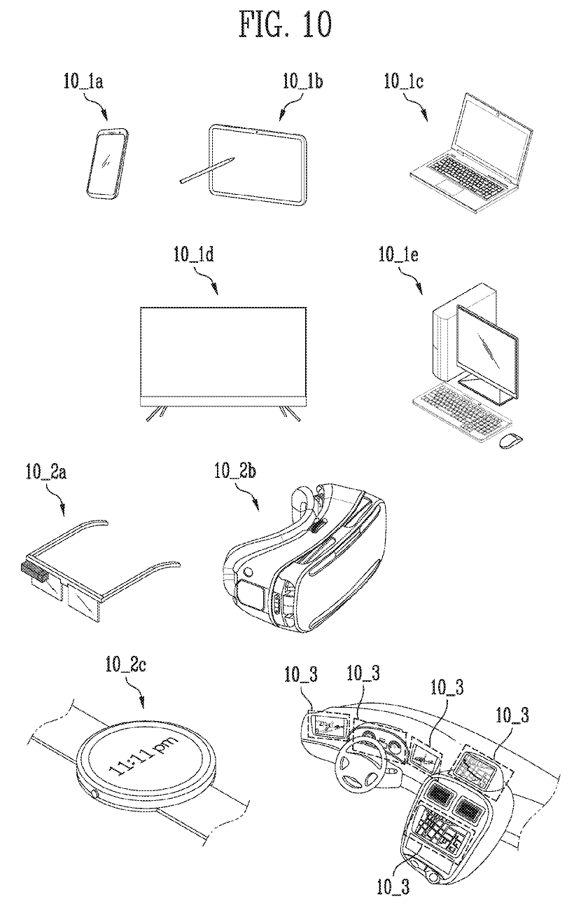

FIG. 10 is schematic diagrams of an electronic device in accordance with various embodiments.

Referring to FIG. 10, various electronic devices 10 to which the display device 100 according to the embodiments is applied may include an electronic device for image display, such as a smartphone 10_1a, a tablet PC 10_1b, a laptop 10_1c, a TV 10_1d, and a desk monitor 10_1e, as well as a wearable electronic device including a display module, such as smart glasses 10_2a, a head-mounted display 10_2b, and a smart watch 10_2c, a vehicle electronic device 10_3 including a display module, such as a CID (Center Information Display) located on an instrument panel, a center fascia, and a dashboard of an automobile, a room mirror display, and the like.

Next will be described a method for manufacturing a deposition mask according to the above-described embodiments.

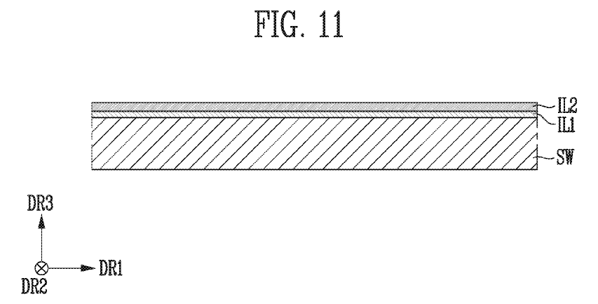

FIGS. 11 to 16 are process operation cross-sectional views of a method of manufacturing a deposition mask according to one or more embodiments. FIGS. 11 to 16 are cross-sectional views for describing the method for manufacturing the deposition mask of FIG. 2, which are briefly illustrated and detailed reference numerals are omitted for convenience of description.

Referring to FIG. 11, first, a base substrate SW is prepared, and a first inorganic layer IL1 and a second inorganic layer IL2 are formed (e.g., sequentially) on the base substrate SW. The base substrate SW may include silicon. The first inorganic layer IL1 may be on or above the base substrate SW. The first inorganic layer IL1 may be directly on the base substrate SW. For example, the first inorganic layer IL1 can be deposited on the base substrate SW. The first inorganic layer IL1 may include silicon oxide (SiOx), but is not necessarily limited thereto.

The second inorganic layer IL2 may be on or above the first inorganic layer IL1. The second inorganic layer IL2 may be directly on the first inorganic layer IL1. For example, the second inorganic layer IL2 can be deposited on the first inorganic layer IL1. The second inorganic layer IL2 may include, but is not necessarily limited to, silicon nitride (SiNx).

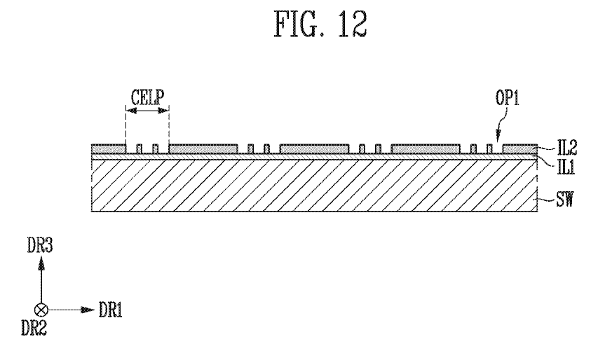

Referring to FIG. 12, cell opening regions CELP are then formed in the second inorganic layer IL2. The second inorganic layer IL2 may be patterned to define cell openings OP1 of the cell opening regions CELP. The cell openings OP1 may penetrate the second inorganic layer IL2 to at least partially expose the first inorganic layer IL1.

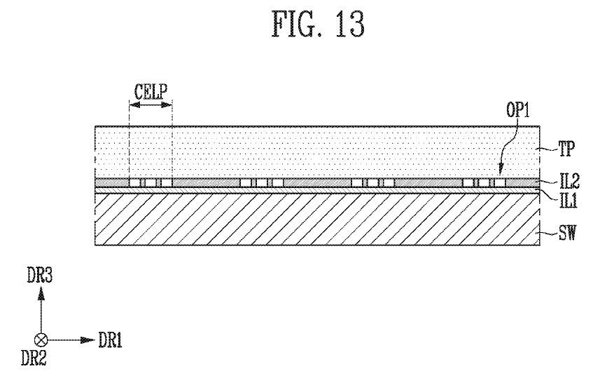

Referring to FIG. 13, a template TP is then attached onto the second inorganic layer IL2. The template TP may be attached and moved on the second inorganic layer IL2. The template TP may have a shape corresponding to the shape of the second inorganic layer IL2 (or the base substrate SW), but is not necessarily limited thereto. In one or more embodiments, the template TP may include, but is not necessarily limited to, at least one of quartz, glass, silica, zirconia.

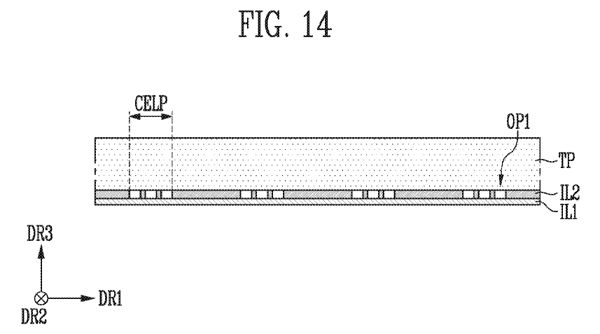

Referring to FIG. 14, the base substrate SW is then removed. The base substrate SW may be removed by a chemical mechanical polishing (CMP) or etching process. One side of the first inorganic layer IL1 may be exposed as the base substrate SW is removed.

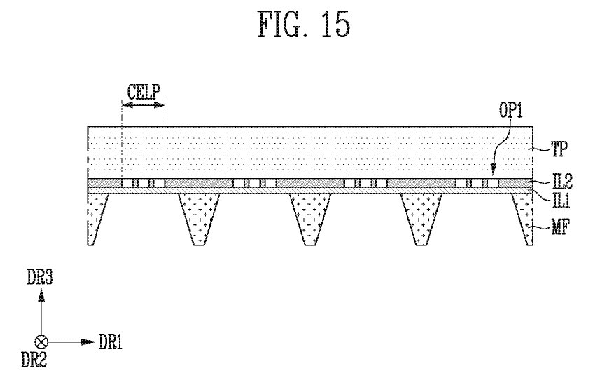

Referring to FIG. 15, a mask frame MF is then bonded on one side of the first inorganic layer IL1. In one or more embodiments, an adhesive layer may be further located between the first inorganic layer IL1 and the mask frame MF, but is not necessarily limited thereto. According to one or more embodiments, the first inorganic layer IL1 and the mask frame MF may be coupled in various manners, such as brazing, soldering, anodic bonding, or silicon fusion bonding.

The mask frame MF may be composed of a material having a coefficient of thermal expansion that is less than or lower than the coefficient of thermal expansion of the base substrate SW. In one or more embodiments, the mask frame MF may include INVAR^{TM} (INVAR^{TM} being a registered trademark of APERAM ALLOYS IMPHY, JOINT STOCK COMPANY, FRANCE). For example, the mask frame MF may include a nickel-iron alloy of which 36% consists of nickel and 64% consists of iron. As described above, in the case where the mask frame MF includes INVAR^{TM}, even if the temperature rises during the continuous deposition, the thermal expansion of the mask frame MF can be reduced or minimized, and thus the reliability of the deposition process can be improved.

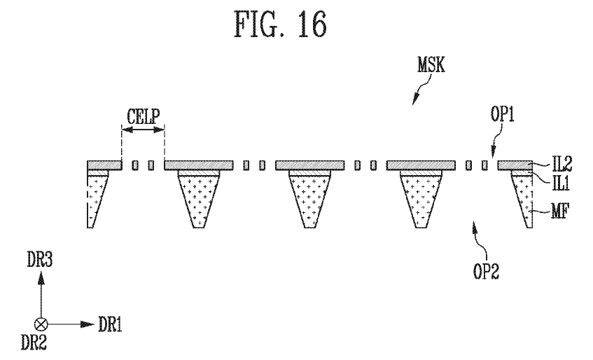

Referring to FIG. 16, the first inorganic layer IL1 is then etched, and the template TP is separated from the second inorganic layer IL2. As an example, the first inorganic layer IL1 exposed by the mask frame MF may be etched to form the opening patterns OP2. The opening patterns OP2 may have a shape penetrating the mask frame MF and the first inorganic layer IL1. The opening pattern OP2 may overlap the cell opening region CELP in the third direction DR3. The opening pattern OP2 may overlap the cell openings OP1 of the cell opening region CELP in the third direction DR3.

According to the above, it is possible to reduce or minimize the thermal expansion of the mask frame MF by using the mask frames MF including INVAR^{TM} (INVAR^{TM} being a registered trademark of APERAM ALLOYS IMPHY, JOINT STOCK COMPANY, FRANCE). Therefore, even if the temperature rises during the continuous deposition, the interval between the cell opening regions CELP can be kept constant, so that the reliability of the continuous deposition process can be improved.

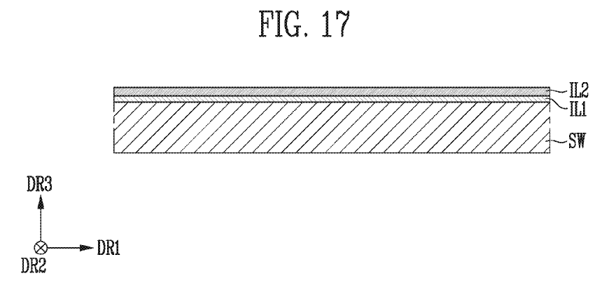

FIGS. 17 to 22 are process operation cross-sectional views of a method of manufacturing a deposition mask according to one or more embodiments. FIGS. 17 to 22 are cross-sectional views for describing the method for manufacturing the deposition mask of FIG. 3, which are briefly illustrated and detailed reference numerals are omitted for convenience of description.

Referring to FIG. 17, first, a base substrate SW is prepared, and a first inorganic layer IL1 and a second inorganic layer IL2 are formed (e.g., sequentially) on or above the base substrate SW. The base substrate SW may include silicon. The first inorganic layer IL1 may be on or above the base substrate SW. The first inorganic layer IL1 may be directly on the base substrate SW. For example, the first inorganic layer IL1 can be deposited on the base substrate SW. The first inorganic layer IL1 may include silicon oxide (SiOx), but is not necessarily limited thereto.

The second inorganic layer IL2 may be on or above the first inorganic layer IL1. The second inorganic layer IL2 may be directly on the first inorganic layer IL1. For example, the second inorganic layer IL2 can be deposited on the first inorganic layer IL1. The second inorganic layer IL2 may include, but is not necessarily limited to, silicon nitride (SiNx).

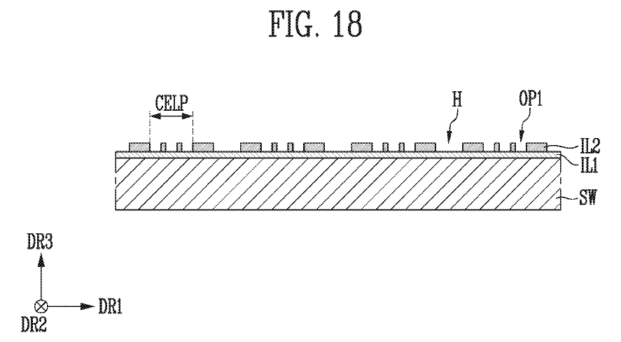

Referring to FIG. 18, cell opening regions CELP and opening holes H are then formed in the second inorganic layer IL2. The second inorganic layer IL2 may be patterned to form cell openings OP1 of the cell opening region CELP. The cell openings OP1 may penetrate the second inorganic layer IL2 to at least partially expose the first inorganic layer IL1. The second inorganic layer IL2 may be patterned to form opening holes H. The opening holes H may penetrate the second inorganic layer IL2 to at least partially expose the first inorganic layer IL1. The cell openings OP1 and the opening holes H may be formed concurrently or substantially simultaneously in the same process.

The opening holes H may each be formed between the cell opening regions CELP. For example, the opening hole H may be between the cell opening regions CELP spaced apart from each other. The opening holes H may serve to separate adjacent cell opening regions CELP from one another. In this case, as described above, even if the position of at least one of the cell opening regions CELP is changed due to a temperature rise in the process of continuous deposition, it is possible to reduce or prevent separation of the cell opening regions CELP from each other to otherwise affect the position of the adjacent cell opening regions CELP.

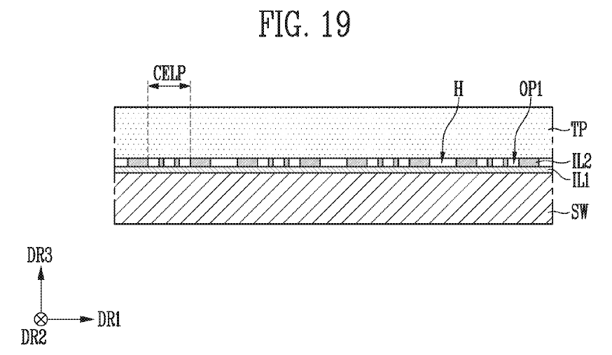

Referring to FIG. 19, the template TP is then attached onto the second inorganic layer IL2. The template TP may be attached and moved on the second inorganic layer IL2. The template TP may have a shape corresponding to the shape of the second inorganic layer IL2 (or the base substrate SW), but is not necessarily limited thereto. In one or more embodiments, the template TP may include, but is not necessarily limited to, at least one of quartz, glass, silica, zirconia.

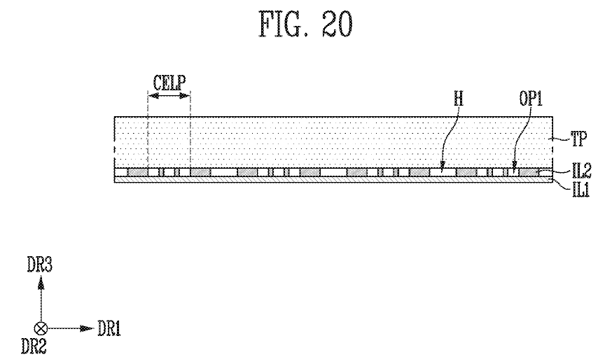

Referring to FIG. 20, the base substrate SW is then removed. The base substrate SW may be removed by a chemical mechanical polishing (CMP) or etching process. One side of the first inorganic layer IL1 may be exposed as the base substrate SW is removed.

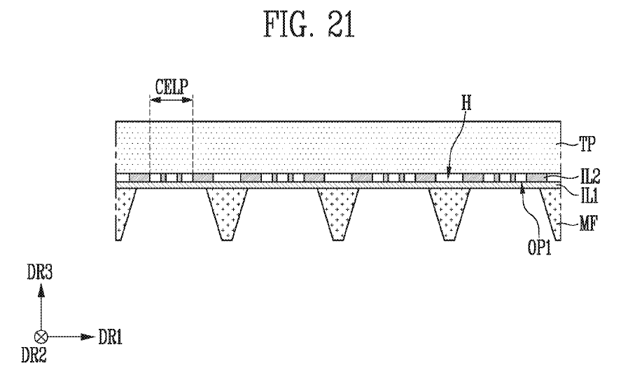

Referring to FIG. 21, a mask frame MF is then bonded on one side of the first inorganic layer IL1. The mask frame MF may overlap the opening holes H in the third direction DR3. In one or more embodiments, an adhesive layer may be further located between the first inorganic layer IL1 and the mask frame MF, but is not necessarily limited thereto. According to one or more embodiments, the first inorganic layer IL1 and the mask frame MF may be coupled in various manners, such as brazing, soldering, anodic bonding, or silicon fusion bonding.

The mask frame MF may be composed of a material having a coefficient of thermal expansion that is less than or lower than the coefficient of thermal expansion of the base substrate SW. In one or more embodiments, the mask frame MF may include a nickel-iron alloy (e.g., INVAR^{TM} (INVAR^{TM} being a registered trademark of APERAM ALLOYS IMPHY, JOINT STOCK COMPANY, FRANCE)). For example, the mask frame MF may include a nickel-iron alloy of which 36% consists of nickel and 64% consists of iron. As described above, in the case where the mask frame MF includes INVAR^{TM} (INVAR^{TM} being a registered trademark of APERAM ALLOYS IMPHY, JOINT STOCK COMPANY, FRANCE), even if the temperature rises during the continuous deposition, the thermal expansion of the mask frame MF can be reduced or minimized, and thus the reliability of the deposition process can be improved.

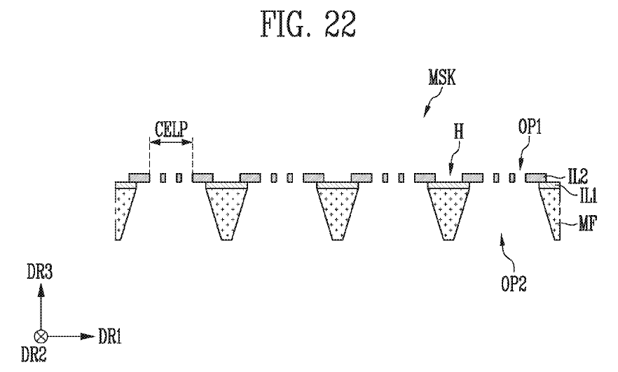

Referring to FIG. 22, the first inorganic layer IL1 is then etched, and the template TP is separated from the second inorganic layer IL2. As an example, the first inorganic layer IL1 exposed by the mask frame MF may be etched to form the opening patterns OP2. The opening patterns OP2 may have a shape penetrating the mask frame MF and the first inorganic layer IL1. The opening pattern OP2 may overlap the cell opening region CELP in the third direction DR3. The opening pattern OP2 may overlap the cell openings OP1 of the cell opening region CELP in the third direction DR3.

According to the above, it is possible to reduce or minimize the thermal expansion of the mask frame MF by using the mask frames MF including INVAR^{TM} (INVAR^{TM} being a registered trademark of APERAM ALLOYS IMPHY, JOINT STOCK COMPANY, FRANCE). Therefore, even if the temperature rises during the continuous deposition, the interval between the cell opening regions CELP can be kept constant, so that the reliability of the continuous deposition process can be improved.

In addition, as the cell opening regions CELP are separated from each other by the opening holes H, even if the position of at least one of the cell opening regions CELP is changed due to a temperature rise in the process of continuous deposition, it is possible to reduce or prevent the likelihood of the position of the adjacent cell opening regions CELP being affected.

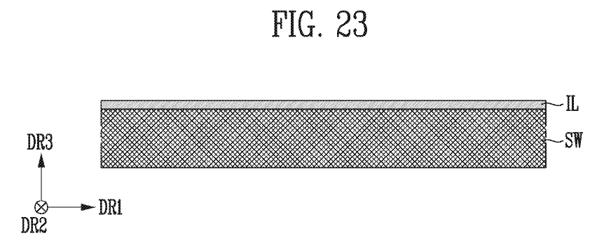

FIGS. 23 to 28 are process operation cross-sectional views of a method of manufacturing a deposition mask according to one or more embodiments. FIGS. 23 to 28 are cross-sectional views for describing the method for manufacturing the deposition mask of FIG. 4, which are briefly illustrated and detailed reference numerals are omitted for convenience of description.

Referring to FIG. 23, first, the base substrate SW is prepared, and the inorganic layer IL is formed on or above the base substrate SW. The base substrate SW may include silicon. The inorganic layer IL may be on or above the base substrate SW. The inorganic layer IL may be directly on the base substrate SW. For example, the inorganic layer IL can be deposited on the base substrate SW. The inorganic layer IL may include, but is not necessarily limited to, silicon nitride (SiNx).

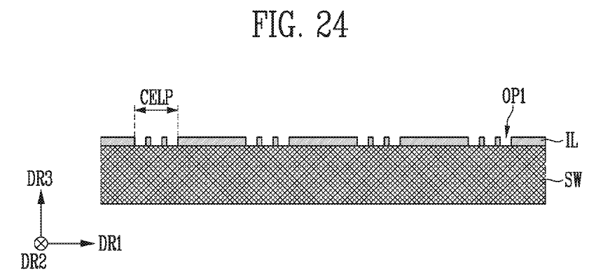

Referring to FIG. 24, cell opening regions CELP are then formed in the inorganic layer IL. The inorganic layer IL may be patterned to form the cell openings OP1 of the cell opening region CELP. The cell openings OP1 may penetrate the inorganic layer IL to at least partially expose the base substrate SW.

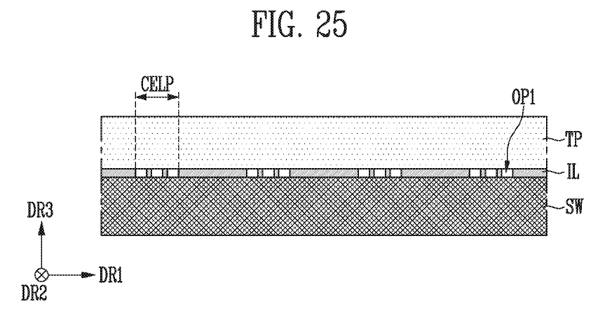

Referring to FIG. 25, the template TP is then bonded onto the inorganic layer IL. The template TP may be attached and moved on the inorganic layer IL. The template TP may have a shape corresponding to the shape of the inorganic layer IL (or the base substrate SW), but is not necessarily limited thereto. In one or more embodiments, the template TP may include, but is not necessarily limited to, at least one of quartz, glass, silica, zirconia.

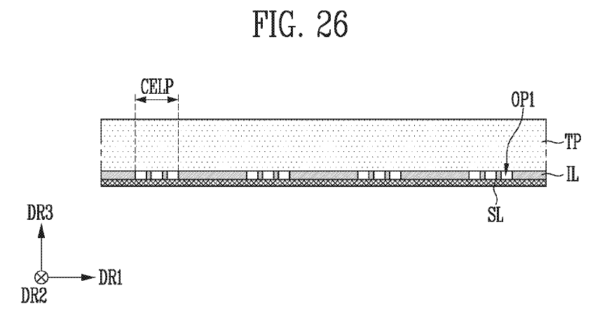

Referring to FIG. 26, the base substrate SW is then formed thin to form the silicon layer SL. For example, the base substrate SW may be thinned by chemical mechanical polishing (CMP) or the like, but is not necessarily limited thereto. In one or more embodiments, the thickness of the silicon layer SL in the third direction DR3 may be, but is not necessarily limited to, about 10 μm to about 100 μm.

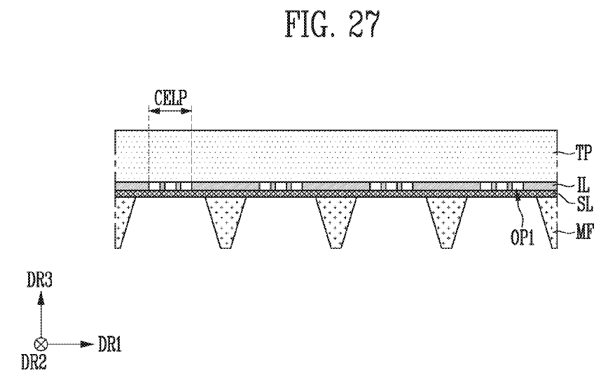

Referring to FIG. 27, the mask frame MF is then bonded on one surface of the silicon layer SL. In one or more embodiments, an adhesive layer may be further located between the inorganic layer IL and the mask frame MF, but is not necessarily limited thereto. According to one or more embodiments, the inorganic layer IL and the mask frame MF may be coupled in various manners, such as brazing, soldering, anodic bonding, or silicon fusion bonding.

The mask frame MF may be composed of a material having a coefficient of thermal expansion that is less than or lower than the coefficient of thermal expansion of the silicon layer SL. In one or more embodiments, the mask frame MF may include a nickel-iron alloy (e.g., INVAR^{TM} (INVAR^{TM} being a registered trademark of APERAM ALLOYS IMPHY, JOINT STOCK COMPANY, FRANCE)). For example, the mask frame MF may include a nickel-iron alloy of which 36% consists of nickel and 64% consists of iron. As described above, in the case where the mask frame MF includes INVAR^{TM} (INVAR^{TM} being a registered trademark of APERAM ALLOYS IMPHY, JOINT STOCK COMPANY, FRANCE), even if the temperature rises during the continuous deposition, the thermal expansion of the mask frame MF can be reduced or minimized, and thus the reliability of the deposition process can be improved.

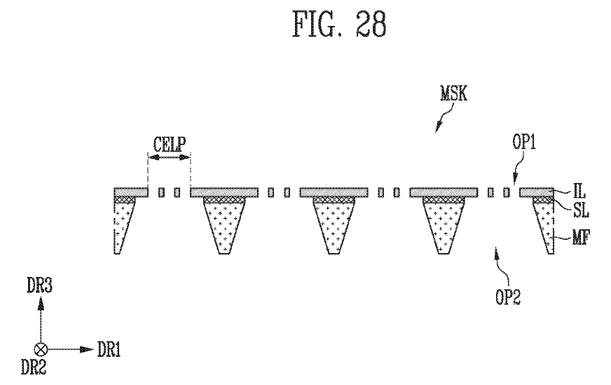

Referring to FIG. 28, the silicon layer SL is then etched, and the template TP is separated from the inorganic layer IL. As an example, the silicon layer SL exposed by the mask frame MF may be etched to form the opening patterns OP2. The opening patterns OP2 may have a shape penetrating the mask frame MF and the silicon layer SL. The opening pattern OP2 may overlap the cell opening region CELP in the third direction DR3. The opening pattern OP2 may overlap the cell openings OP1 of the cell opening region CELP in the third direction DR3.

According to the above, it is possible to reduce or minimize the thermal expansion of the mask frame MF by using the mask frames MF including INVAR^{TM} (INVAR^{TM} being a registered trademark of APERAM ALLOYS IMPHY, JOINT STOCK COMPANY, FRANCE). Therefore, even if the temperature rises during the continuous deposition, the interval between the cell opening regions CELP can be kept constant, so that the reliability of the continuous deposition process can be improved.

Although embodiments have been described herein, other embodiments and variations can be derived from the above description. Accordingly, the present disclosure is not limited to these embodiments, but extends to the claims set forth below, as well as various obvious modifications and equivalents.

What is claimed is:

1. A deposition mask comprising:
a mask frame comprising a nickel-iron alloy;
a first inorganic layer above the mask frame, the mask frame and the first inorganic layer defining opening patterns; and
a second inorganic layer above the first inorganic layer, and defining cell openings at cell opening regions.

2. The deposition mask of claim 1, wherein the opening patterns overlap the cell opening regions.

3. The deposition mask of claim 1, wherein the first inorganic layer comprises silicon oxide, and
wherein the second inorganic layer comprises silicon nitride.

4. The deposition mask of claim 1, wherein the second inorganic layer further defines an opening hole between the cell opening regions.

5. The deposition mask of claim 4, wherein the opening hole is between adjacent ones of the cell opening regions.

6. The deposition mask of claim 4, wherein the opening hole overlaps the mask frame.

7. The deposition mask of claim 4, wherein the opening hole overlaps the first inorganic layer.

8. The deposition mask of claim 4, wherein the opening hole exposes the first inorganic layer.

9. An electronic device comprising:
a processor; and
a display device comprising pixels, and configured to display an image under control of the processor, the display device being manufactured using the deposition mask of claim 1.

10. The electronic device of claim 9, wherein the display device comprises:
a first electrode;
a second electrode above the first electrode; and
a light-emitting layer between the first electrode and the second electrode.

11. A method for manufacturing a deposition mask, the method comprising:
forming a first inorganic layer above a base substrate;
forming a second inorganic layer above the first inorganic layer;
forming cell opening regions in the second inorganic layer;
bonding a template onto the second inorganic layer;
removing the base substrate from the first inorganic layer;
bonding a mask frame to a surface of the first inorganic layer; and
removing the template from the second inorganic layer.

12. The method of claim 11, wherein a coefficient of thermal expansion of the mask frame is less than a coefficient of thermal expansion of the base substrate.

13. The method of claim 11, wherein the mask frame comprises a nickel-iron alloy.

14. The method of claim 11, further comprising etching the first inorganic layer to form opening patterns.

15. The method of claim 14, wherein the opening patterns overlap the cell opening regions.

16. The method of claim 11, wherein the cell opening regions correspond to cell openings defined by the second inorganic layer.

17. The method of claim 11, wherein the first inorganic layer comprises silicon oxide, and
wherein the second inorganic layer comprises silicon nitride.

18. The method of claim 11, further comprising forming an opening hole between adjacent ones of the cell opening regions.

19. The method of claim 18, wherein the adjacent ones of the cell opening regions are separated from each other by the opening hole.

20. The method of claim 18, wherein the opening hole exposes the first inorganic layer.
